(19) United States
(12) Patent Application Publication
(10) Pub. No.: US 2019/0173398 A1
(43) Pub. Date: Jun. 6, 2019

(54) ENVIRONMENTAL PROTECTION DEVICE WITH MULTI-LEVEL WATERPROOF PIEZOELECTRIC CONVERSION OF ENVIRONMENTAL MECHANICAL ENERGY CYCLE

(71) Applicant: Kwok Ngai MAK, Hong Kong (HK)

(72) Inventor: Kwok Ngai MAK, Hong Kong (HK)

(21) Appl. No.: 15/848,257

(22) Filed: Dec. 20, 2017

(30) Foreign Application Priority Data
Dec. 1, 2017 (CN) 201711250702.5

(51) Int. Cl. H02N 2/18; H01L 41/053; H01L 41/113

(52) U.S. Cl. CPC H02N 2/18; H01L 41/113; H01L 41/0536; H01L 41/0533

(57) ABSTRACT

The invention discloses an environmental protection device with multi-level waterproof piezoelectric conversion of environmental mechanical energy cycle which includes a lower housing, an upper housing, a waterproof mechanism, a lower permanent magnet, a coil mechanism, an upper permanent magnet, and an auxiliary power generator. The waterproof mechanism is a flexible case disposed between the lower housing and the upper housing. The lower permanent magnet is fixedly disposed at the bottom of the first cavity. The coil mechanism is disposed above the lower permanent magnet. The coil mechanism includes a magnetically conductive shell and a coil and fan-shaped magnetic blocks. The lower end surface of the upper housing is provided with an extension block, an upper permanent magnet, and an auxiliary power generator. The environmental protection device with multi-level waterproof piezoelectric conversion of environmental mechanical energy cycle of the invention has advantages of simple and reasonable structure, being easy to use, reliable and safe, and high conversion rate, etc. It effectively solves the problem regarding insufficient utilization in energy caused by the crowd.

### FIELD OF THE INVENTION

The invention relates to environmental protection and energy saving devices. In particular, the invention relates to an environmental protection device with multi-level waterproof piezoelectric conversion of environmental mechanical energy cycle.

### BACKGROUND

In the known art, energy refers to the substance that provides energy conversion to the nature, and is the material basis for human activities. In a sense, the development of human society is inseparable from the emergence of high-quality energy and the use of advanced energy technologies. In today's world, with the continuous growth of population and the gradual depletion of non-renewable energy, how to develop and obtain more energy is a common concern of all people and mankind all over the world. In the past, most people focused on energy sources such as ores, nuclear energy and wind energy in the field of new energy development but paid little attention to the energy generated by crowded activities. Therefore, it is necessary to invent a device to utilize and convert energy generated by human activities.

### SUMMARY OF THE INVENTION

The technical problem to be solved is to overcome the above-mentioned deficiency by providing an environmental protection device with multi-level waterproof piezoelectric conversion of environmental mechanical energy cycle. It has advantages of simple and reasonable structure, being easy to use, reliable and safe, and high conversion rate, etc. It effectively solves the problem regarding insufficient utilization in energy caused by the crowd.

The technical solution of the invention is to provide an environmental protection device with multi-level waterproof piezoelectric conversion of environmental mechanical energy cycle which includes a lower housing, an upper housing, a waterproof mechanism, a lower permanent magnet, a coil mechanism, an upper permanent magnet, and an auxiliary power generator. The lower housing is provided with a plurality of guide sleeves. The lower end surface of the upper housing is provided with a plurality of guide shafts which are sleeved with the guide sleeves. The waterproof mechanism is a flexible case disposed between the lower housing and the upper housing. Two ends of the waterproof mechanism are fixedly connected to the lower housing and the upper housing, respectively.

The lower housing is provided with a groove and a first cavity. The lower permanent magnet is fixedly disposed at the bottom of the first cavity. The coil mechanism is disposed above the lower permanent magnet by a plurality of hydraulic rods positioned at the bottom. A buffer spring, a piezoelectric ceramic and an insulation pad are arranged in the groove from top to bottom.

The coil mechanism includes a magnetically conductive shell and a coil disposed in the inner cavity of the magnetically conductive shell. The magnetically conductive shell is provided with a connecting protrusion, a first slide rail, a second slide rail, and a through hole. The connecting protrusion is fixedly connected to a driving shaft of the hydraulic rod. The first slide rail and the second slide rail are symmetrically slidly provided with fan-shaped magnetic blocks. The fan-shaped magnetic blocks are connected to each other via a connecting shaft.

The lower end surface of the upper housing is provided with an extension block that is slidly sleeved with the groove, an upper permanent magnet, and an auxiliary power generator. The lower end of the extension block abuts the buffer spring. The upper permanent magnet is provided with a helical shaft which is provided with a plurality of helical grooves. The helical grooves are clamped with the connecting shaft. The auxiliary power generator includes a thermoelectric power generation film disposed on the upper end surface of the upper housing, a solar panel disposed on the thermoelectric power generation film, and a toughened glass cover that wraps around the thermoelectric power generation film and the solar panel.

In a further embodiment, the upper housing is provided with a plurality of a first bumps and second bumps. The first bump is provided with a positioning hole. The second bump is provided with a positioning shaft. The positioning hole is sleeved with the positioning shaft on the adjacent upper housings.

In a further embodiment, a spindle of the hydraulic rod is sleeved with a telescopic sleeve. A tensioned spring is arranged between the telescopic sleeve and the spindle of the hydraulic rod.

In a further embodiment, the upper permanent magnet is provided with a convex shaft which is provided with a buffer cover.

In a further embodiment, the coil, the thermoelectric power generation film, the solar panel and the piezoelectric ceramic are connected with an external electric energy storage device.

In a further embodiment, the coil is composed of a transversely wound inner layer and an outer layer longitudinally wound on the surface of the inner layer.

In a further embodiment, the lower housing and the upper housing are made of non-magnetizable alloy material. The surface of the lower housing, and the upper housing and the waterproof mechanism is provided with a shielding layer for shielding the electromagnetic wave.

In a further embodiment, the upper end surface of the lower permanent magnet and the lower end surface of the upper permanent magnet have the same polarity.

The technical effect of the invention is to provide an environmental protection device with multi-level waterproof piezoelectric conversion of environmental mechanical energy cycle which includes a lower housing, an upper housing, a waterproof mechanism, a lower permanent magnet, a coil mechanism, an upper permanent magnet, and an auxiliary power generator. The lower housing, the waterproof mechanism, and the upper housing are arranged from top to bottom. The waterproof mechanism can prevent water from getting inside of the device and damaging the device. The upper permanent magnet and the lower permanent magnet have the same polarity on opposite sides, and utilize their repulsive force instead of a spring as a resetting force to avoid the mechanical fatigue caused by the resetting of the spring which affects the normal use of the invention. This extends the service life of the device of the invention. The lower permanent magnet, the coil mechanism, and the upper permanent magnet can continuously move relative to each other to extend the power generation time and increase the conversion efficiency, when they are pressed by the outside force. The piezoelectric ceramics assist in generating electric power by the piezoelectric effect. The polar panel assists in generating electric power by the sunlight. The thermoelectric power generation film assists in generating electric power by the temperature difference between the internal and external cavities to further increase the energy conversion efficiency. It has advantages of simple and reasonable structure, being easy to use, reliable and safe, and high conversion rate, etc. It effectively solves the problem regarding insufficient utilization in energy caused by the crowd.

### BRIEF DESCRIPTION OF THE DRAWINGS

The invention is illustrated by the following figures and embodiments.

FIG. 1 shows a schematic diagram of external whole structure of an environmental protection device with multi-level waterproof piezoelectric conversion of environmental mechanical energy cycle in an accordance with an example embodiment.

FIG. 2 shows a cross section of whole structure of an environmental protection device with multi-level waterproof piezoelectric conversion of environmental mechanical energy cycle in an accordance with an example embodiment.

FIG. 3 shows a schematic diagram of an upper housing of an environmental protection device with multi-level waterproof piezoelectric conversion of environmental mechanical energy cycle in an accordance with an example embodiment.

FIG. 4 shows a schematic diagram of a lower housing of an environmental protection device with multi-level waterproof piezoelectric conversion of environmental mechanical energy cycle in an accordance with an example embodiment.

FIG. 5 shows a top view of a coil mechanism of an environmental protection device with multi-level waterproof piezoelectric conversion of environmental mechanical energy cycle in an accordance with an example embodiment.

FIG. 6 shows a cross section of a coil mechanism of an environmental protection device with multi-level waterproof piezoelectric conversion of environmental mechanical energy cycle in an accordance with an example embodiment.

FIG. 7 shows the connection of a hydraulic rod and a coil mechanism of an environmental protection device with multi-level waterproof piezoelectric conversion of environmental mechanical energy cycle in an accordance with an example embodiment.

FIG. 8 shows a schematic diagram of an upper permanent magnet of an environmental protection device with multi-level waterproof piezoelectric conversion of environmental mechanical energy cycle in an accordance with an example embodiment.

FIG. 9 shows a cross section of a helical shaft of an upper permanent magnet of an environmental protection device with multi-level waterproof piezoelectric conversion of environmental mechanical energy cycle in an accordance with an example embodiment.

The reference numbers of the figures are as follows:
1: lower housing; 11: guide sleeve; 12: groove; 121: buffer spring; 122: piezoelectric ceramic; 123: insulation pad; 13: first cavity; 131: hydraulic rod; 132: tensioned spring; 133: telescopic sleeve; 2: upper housing; 21: first bump; 22: second bump; 23: guide shaft; 24: extension block; 3: waterproof mechanism; 4: lower permanent magnet; 5: coil mechanism; 51: magnetically conductive shell; 511: connecting protrusion; 512: first slide rail; 513: second slide rail; 52: through hole; 53: coil; 54: fan-shaped magnetic block; 55: connecting shaft; 6: upper permanent magnet; 61: helical shaft; 611: helical groove; 62: convex shaft; 63: buffer cover; 7: auxiliary power generator; 71: solar panel; 72: thermoelectric power generation film; 73: toughed glass cover.

### DETAILED DESCRIPTION

The invention is illustrated in accordance with figures. The figures as simplified diagrams demonstrate the basic structures of the apparatus of embodiments of the invention. Thus, the invention is not limited to the figures.

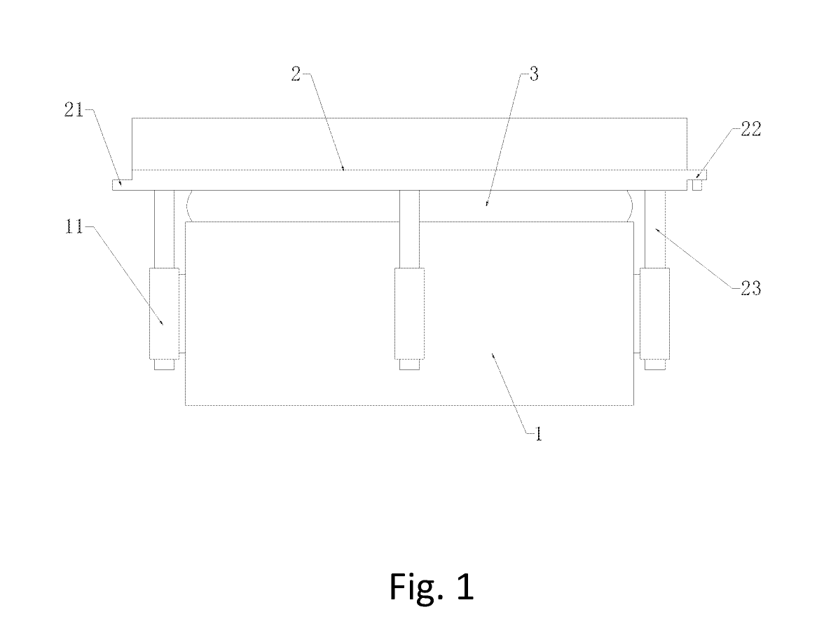

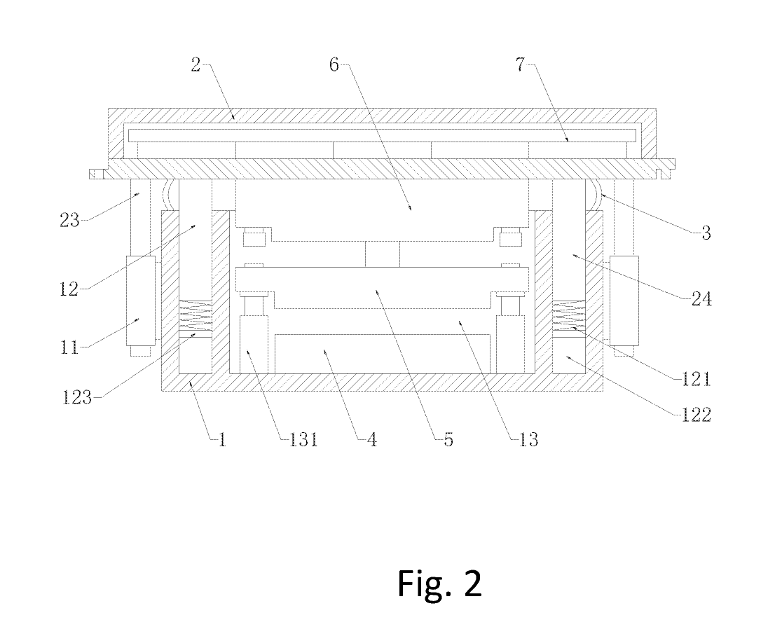

As shown in FIGS. 1 and 2, an environmental protection device with multi-level waterproof piezoelectric conversion of environmental mechanical energy cycle includes a lower housing 1, an upper housing 2, a waterproof mechanism 3, a lower permanent magnet 4, a coil mechanism 5, an upper permanent magnet 6, and an auxiliary power generator 7. The lower housing 1 is provided with a plurality of guide sleeves 11. The lower end surface of the upper housing 2 is provided with a plurality of guide shafts 23 which are sleeved with the guide sleeves 11. The waterproof mechanism 3 is a flexible case disposed between the lower housing 1 and the upper housing 2. Two ends of the waterproof mechanism 3 are fixedly connected to the lower housing 1 and the upper housing 2, respectively. In an embodiment, two ends of the waterproof mechanism 3 are provided with an annular plate with a latch tooth. The lower housing 1 and the upper housing 2 are provided with a tooth slot that adapts to the annular plate. The lower housing 1 and the upper housing 2 are clamped by the rotation of the tooth slot and the annular plate. A rubber seal is provided in the tooth slot.

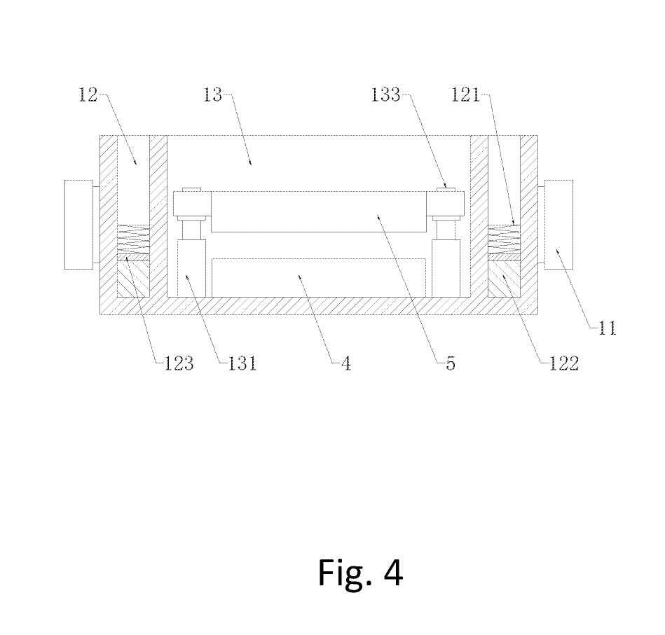

As shown in FIG. 4, the lower housing 1 is provided with a groove 12 and a first cavity 13. The lower permanent magnet 4 is fixedly disposed at the bottom of the first cavity 13. The coil mechanism 5 is disposed above the lower permanent magnet 4 by a plurality of hydraulic rods 131 positioned at the bottom. A buffer spring 121, a piezoelectric ceramic 122 and an insulation pad 123 are arranged in the groove 12 from top to bottom.

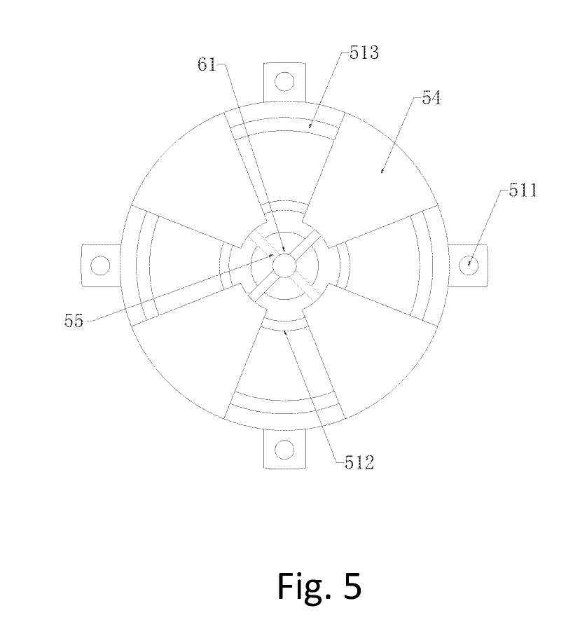

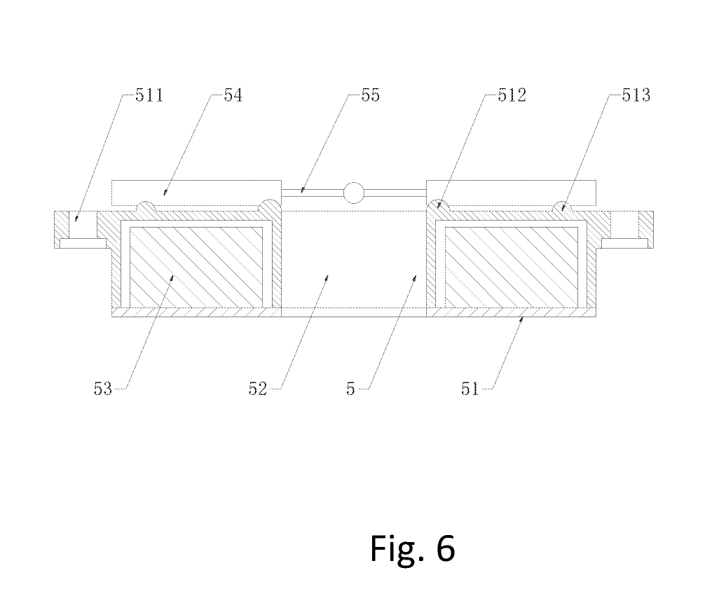

As shown in FIGS. 5 and 6, the coil mechanism 5 includes a magnetically conductive shell 51 and a coil 53 disposed in the inner cavity of the magnetically conductive shell 51. The magnetically conductive shell 51 is provided with a connecting protrusion 511, a first slide rail 512, a second slide rail 513, and a through hole 52. The connecting protrusion 511 is fixedly connected to a driving shaft of the hydraulic rod 131. The first slide rail 512 and the second slide rail 513 are symmetrically slidly provided with fan-shaped magnetic blocks 54. The fan-shaped magnetic blocks 54 are connected to each other via a connecting shaft 55.

When the upper housing 2 moves downward, the upper permanent magnet 6 approaches the coil mechanism 5 downward, so that the magnetic induction line of the upper permanent magnet 6 continues to cut the coil 53. When the upper housing 2 moves to contact with the coil mechanism 5, the upper housing drives the coil mechanism 5 to move downward to approach the lower permanent magnet 4 and compress the hydraulic rod 131 so that the magnetic induction line of the lower permanent magnet 4 continues to cut the coil 53.

When the upper housing 2 moves upward, the hydraulic rod is extended, the coil mechanism 5 and the upper permanent magnet 6 move up at the same time, the magnetic induction line of the lower permanent magnet 4 and the coil 53 continue to cut. When the hydraulic rod moves to the top, the upper permanent magnet 6 continues to move upward so that the magnetic field lines of the upper permanent magnet 6 continue to cut the coil 53 until the upper housing 2 moves to the top.

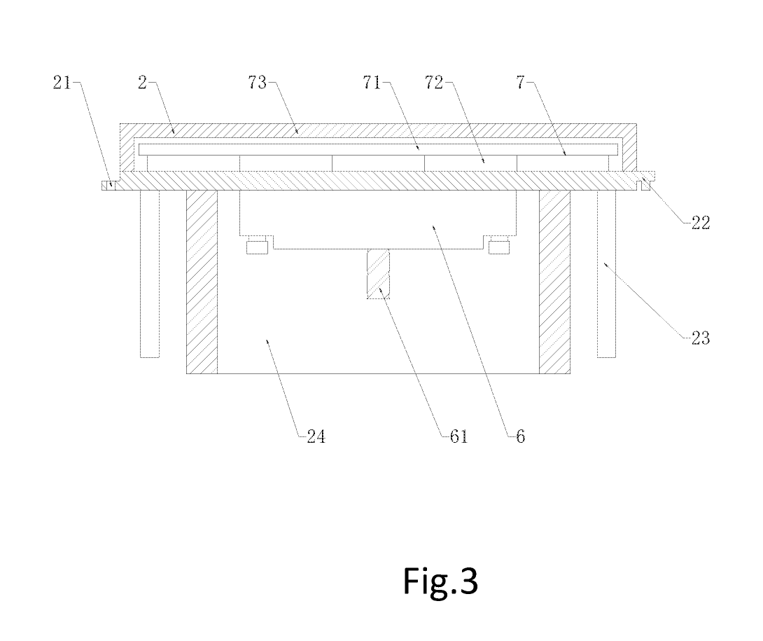

As shown in FIG. 3, the lower end surface of the upper housing 2 is provided with an extension block 24 that is slidly sleeved with the groove 12, an upper permanent magnet 6, and an auxiliary power generator 7. The lower end of the extension block 24 abuts the buffer spring 121. The extension block 24 sequentially presses the buffer spring 121, the insulation pad 123, and the piezoelectric ceramic 122, as the upper housing 2 moves downwards. The piezoelectric ceramic 122 generates electrical power by the piezoelectric effect.

The buffer spring 121 prevents the piezoelectric ceramic 122 from being crushed damage.

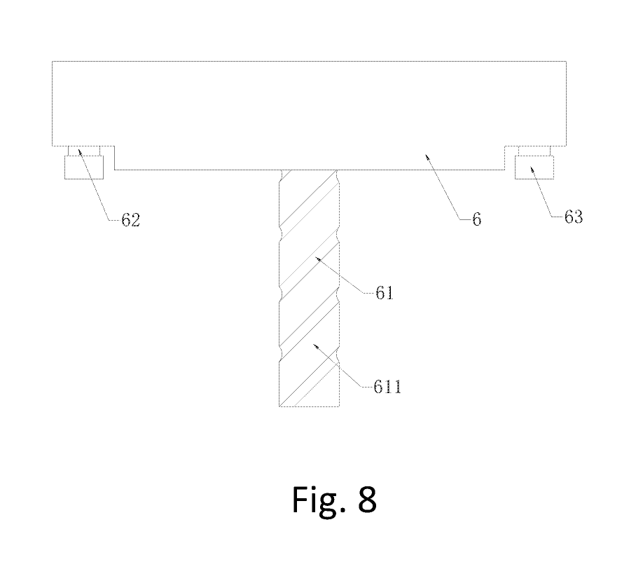

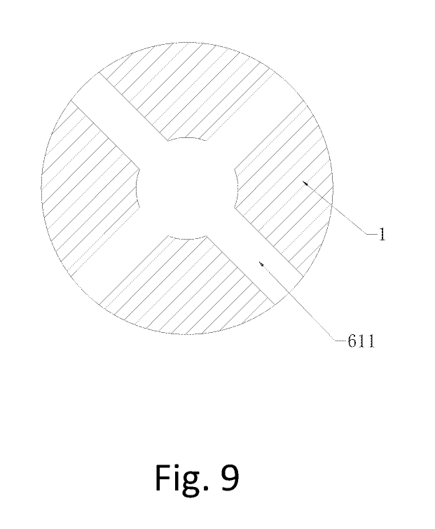

As shown in FIGS. 8 and 9, the upper permanent magnet 6 is provided with a helical shaft 61 which is provided with a plurality of helical grooves 611. The helical grooves 611 are clamped with the connecting shaft 55. When the helical shaft 61 and the coil mechanism 5 move relative to each other, the fan-shaped magnetic block 54 is driven to rotate to make the magnetic induction line cut the coil 53, so that the electric energy is generated in the coil 53.

As shown in FIG. 3, the auxiliary power generator 7 includes a thermoelectric power generation film 72 disposed on the upper end surface of the upper housing 2, a solar panel 71 disposed on the thermoelectric power generation film 72, and a toughened glass cover 73 that wraps around the thermoelectric power generation film 72 and the solar panel 71. The thermoelectric power generation film 72 generates electrical energy by the temperature difference between the internal and external cavities of the invention.

In an embodiment as shown in FIGS. 1, 2 and 3, the upper housing 2 is provided with a plurality of a first bumps 21 and second bumps 22. The first bump 21 is provided with a positioning hole. The second bump 22 is provided with a positioning shaft. The positioning hole is sleeved with the positioning shaft on the adjacent upper housings 2.

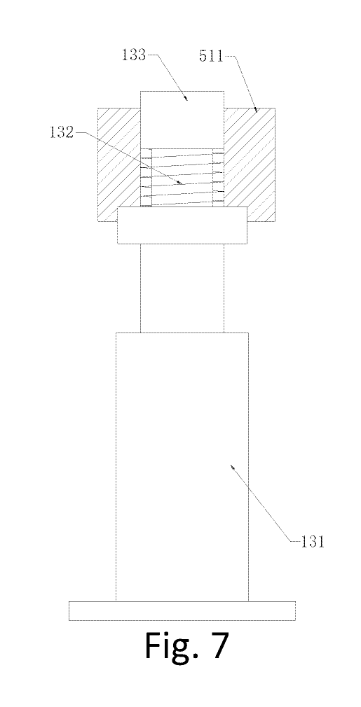

In an embodiment as shown in FIG. 7, a spindle of the hydraulic rod 131 is sleeved with a telescopic sleeve 133. A tensioned spring 132 is arranged between the telescopic sleeve 133 and the spindle of the hydraulic rod 131. The tensioned spring 132 function as a buffer when the upper housing 2 move downwards to contact with the coil mechanism.

In an embodiment as shown in FIG. 8, the upper permanent magnet 6 is provided with a convex shaft 62 which is provided with a buffer cover 63.

In an embodiment, the coil 53, the thermoelectric power generation film 72, the solar panel 71 and the piezoelectric ceramic 122 are connected with an external electric energy storage device.

In an embodiment, the coil 53 is composed of a transversely wound inner layer and an outer layer longitudinally wound on the surface of the inner layer.

The outer layer of the coil 53 can also be wound from enameled wire at other angles to the inner layer. The inner and outer layers can be solid or the inner layer can be annular and the outer ring can be wound around the inner surface.

In an embodiment, the lower housing 1 and the upper housing 2 are made of non-magnetizable alloy material. The surface of the lower housing 1, and the upper housing 2 and the waterproof mechanism 3 is provided with a shielding layer for shielding the electromagnetic wave.

In an embodiment, the upper end surface of the lower permanent magnet 4 and the lower end surface of the upper permanent magnet 6 have the same polarity. In an embodiment, the upper end surface of the lower permanent magnet 4 and the lower end surface of the upper permanent magnet 6 are both N pole. In another embodiment, the upper end surface of the lower permanent magnet 4 and the lower end surface of the upper permanent magnet 6 are both S pole.

An environmental protection device with multi-level waterproof piezoelectric conversion of environmental mechanical energy cycle of the invention includes a lower housing, an upper housing, a waterproof mechanism, a lower permanent magnet, a coil mechanism, an upper permanent magnet, and an auxiliary power generator. The lower housing, the waterproof mechanism, and the upper housing are arranged from top to bottom. The waterproof mechanism can prevent water from getting inside of the device and damaging the device. The upper permanent magnet and the lower permanent magnet have the same polarity on opposite sides, and utilize their repulsive force instead of a spring as a resetting force to avoid the mechanical fatigue caused by the resetting of the spring which affects the normal use of the invention. This extends the service life of the device of the invention. The lower permanent magnet, the coil mechanism, and the upper permanent magnet can continuously move relative to each other to extend the power generation time and increase the conversion efficiency, when they are pressed by the outside force. The piezoelectric ceramics assist in generating electric power by the piezoelectric effect. The polar panel assists in generating electric power by the sunlight. The thermoelectric power generation film assists in generating electric power by the temperature difference between the internal and external cavities to further increase the energy conversion efficiency. It has advantages of simple and reasonable structure, being easy to use, reliable and safe, and high conversion rate, etc. It effectively solves the problem regarding insufficient utilization in energy caused by the crowd.

The exemplary embodiments of the present invention are thus fully described. Although the description referred to particular embodiments, it will be clear to one skilled in the art that the present invention may be practiced with variations of these specific details. Hence this invention should not be construed as limited to the embodiments set forth herein.

What is claimed is:

1. An environmental protection device with multi-level waterproof piezoelectric conversion of environmental mechanical energy cycle, comprising: a lower housing 1; an upper housing 2; a waterproof mechanism 3; a lower permanent magnet 4; a coil mechanism 5; an upper permanent magnet 6; and an auxiliary power generator 7,
wherein the lower housing 1 is provided with a plurality of guide sleeves 11; the lower end surface of the upper housing 2 is provided with a plurality of guide shafts 23 which are sleeved with the guide sleeves 11; the waterproof mechanism 3 is a flexible case disposed between the lower housing 1 and the upper housing 2; two ends of the waterproof mechanism 3 are fixedly connected to the lower housing 1 and the upper housing 2, respectively,
wherein the lower housing 1 is provided with a groove 12 and a first cavity 13; the lower permanent magnet 4 is fixedly disposed at the bottom of the first cavity 13; the coil mechanism 5 is disposed above the lower permanent magnet 4 by a plurality of hydraulic rods 131 positioned at the bottom; a buffer spring 121, a piezoelectric ceramic 122 and an insulation pad 123 are arranged in the groove 12 from top to bottom,
wherein the coil mechanism 5 includes a magnetically conductive shell 51 and a coil 53 disposed in the inner cavity of the magnetically conductive shell 51; the magnetically conductive shell 51 is provided with a connecting protrusion 511, a first slide rail 512, a second slide rail 513, and a through hole 52; the connecting protrusion 511 is fixedly connected to a driving shaft of the hydraulic rod 131; the first slide rail 512 and the second slide rail 513 are symmetrically slidly provided with fan-shaped magnetic blocks 54; the fan-shaped magnetic blocks 54 are connected to each other via a connecting shaft 55,
wherein the lower end surface of the upper housing 2 is provided with an extension block 24 that is slidly sleeved with the groove 12, an upper permanent magnet 6, and an auxiliary power generator 7; the lower end of the extension block 24 abuts the buffer spring 121; the upper permanent magnet 6 is provided with a helical shaft 61 which is provided with a plurality of helical grooves 611; the helical grooves 611 are clamped with the connecting shaft 55; the auxiliary power generator 7 includes a thermoelectric power generation film 72 disposed on the upper end surface of the upper housing 2, a solar panel 71 disposed on the thermoelectric power generation film 72, and a toughened glass cover 73 that wraps around the thermoelectric power generation film 72 and the solar panel 71.

2. The environmental protection device with multi-level waterproof piezoelectric conversion of environmental mechanical energy cycle of claim 1, wherein the upper housing 2 is provided with a plurality of a first bumps 21 and second bumps 22; the first bump 21 is provided with a positioning hole; the second bump 22 is provided with a positioning shaft; the positioning hole is sleeved with the positioning shaft on the adjacent upper housings 2.

3. The environmental protection device with multi-level waterproof piezoelectric conversion of environmental mechanical energy cycle of claim 1, wherein a spindle of the hydraulic rod 131 is sleeved with a telescopic sleeve 133; a tensioned spring 132 is arranged between the telescopic sleeve 133 and the spindle of the hydraulic rod 131.

4. The environmental protection device with multi-level waterproof piezoelectric conversion of environmental mechanical energy cycle of claim 1, wherein the upper permanent magnet 6 is provided with a convex shaft 62 which is provided with a buffer cover 63.

5. The environmental protection device with multi-level waterproof piezoelectric conversion of environmental mechanical energy cycle of claim 1, wherein the coil 53, the thermoelectric power generation film 72, the solar panel 71 and the piezoelectric ceramic 122 are connected with an external electric energy storage device.

6. The environmental protection device with multi-level waterproof piezoelectric conversion of environmental mechanical energy cycle of claim 1, wherein the coil 53 is composed of a transversely wound inner layer and an outer layer longitudinally wound on the surface of the inner layer.

7. The environmental protection device with multi-level waterproof piezoelectric conversion of environmental mechanical energy cycle of claim 1, wherein the lower housing 1 and the upper housing 2 are made of non-magnetizable alloy material; the surface of the lower housing 1, and the upper housing 2 and the waterproof mechanism 3 is provided with a shielding layer for shielding the electromagnetic wave.

8. The environmental protection device with multi-level waterproof piezoelectric conversion of environmental mechanical energy cycle of claim 1, wherein the upper end surface of the lower permanent magnet 4 and the lower end surface of the upper permanent magnet 6 have the same polarity.
